(19) United States
(12) Patent Application Publication
(10) Pub. No.: US 2026/0019724 A1
(43) Pub. Date: Jan. 15, 2026

(54) SYNCHRONIZATION CIRCUIT AND DISTRIBUTED CAMERA SYSTEM

(71) Applicant: KANDAO TECHNOLOGY CO., LTD., Shenzhen (CN)

(72) Inventor: Xiangjun ZHAO, Shenzhen (CN)

(73) Assignee: KANDAO TECHNOLOGY CO., LTD., Shenzhen (CN)

(21) Appl. No.: 19/332,553

(22) Filed: Sep. 18, 2025

Related U.S. Application Data
(63) Continuation of application No. PCT/CN2023/104057, filed on Jun. 29, 2023.

(30) Foreign Application Priority Data
Mar. 21, 2023 (CN) 202310304145.X
Mar. 21, 2023 (CN) 202310306214.0

(51) Int. Cl. H04N 25/76; H04N 23/90; H10F 77/00

(52) U.S. Cl. CPC H04N 25/7795; H04N 23/90; H10F 77/933

(57) ABSTRACT

In a synchronization circuit, a detection control module outputs a first control signal, a detection signal and a second control signal. In a case where the detection signal is received, the main control chip module generates a master clock signal and a frame synchronization signal. In a case where the first control signal is received, the master clock signal transmission module transmits the master clock signal to the output interface module, and the frame synchronization signal transmission module transmits the frame synchronization signal to the output interface module. In a case where the second control signal is received, the master clock signal transmission module transmits the master clock signal to the output interface module, the frame synchronization signal transmission module transmits the frame synchronization signal to the output interface module, and a camera module acquires a picture based on the frame synchronization signal and the master clock signal.

### CROSS-REFERENCE TO RELATED APPLICATIONS

This application is a continuation of International Patent Application No. PCT/CN2023/104057 with a filing date of Jun. 29, 2023, designating the United States, now pending, and further claims priorities to Chinese Patent Application No. 202310306214.0 with a filing date of Mar. 21, 2023, and Chinese Patent Application No. 202310304145.X with a filing date of Mar. 21, 2023. The content of the aforementioned applications, including any intervening amendments thereto, is incorporated herein by reference.

### TECHNICAL FIELD

The present disclosure relates to the field of camera circuits, in particular to a synchronization circuit and a distributed camera system.

### BACKGROUND

In conventional distributed camera systems, since the master clock signals and frame synchronization signals of the image sensors inside all digital cameras operate independently, satisfactory image frame synchronization cannot be achieved. For instance, if the frame rate of the system image is 30 fps, i.e., the system transmits 30 frames of images per second, the temporal discrepancy between image frames can reach approximately 16 milliseconds. If the discrepancies between the master clock signals or frame synchronization signals of different cameras exceed 16 milliseconds, it may lead to errors in the synchronized image frames captured by different cameras.

Therefore, in the existing distributed camera system, there is a technical problem that the synchronization effect of the images output by the respective cameras is poor.

Therefore, it is necessary to provide a synchronization circuit and a distributed camera system to address the aforementioned technical problem.

### SUMMARY OF THE INVENTION

The present disclosure provides a synchronization circuit and a distributed camera system, which effectively solves the technical problem of poor synchronization effect of images output by respective cameras in the existing distributed camera system.

The present disclosure provides a synchronization circuit arranged within each camera of a distributed camera system, including:

an input interface module, configured to input a master clock signal or a frame synchronization signal;

a detection control module, configured to output a first control signal to a master clock signal transmission module and a frame synchronization signal transmission module in a case where the input interface module is connected with a synchronization line; output a detection signal to a main control chip module, and output a second control signal to the master clock signal transmission module and the frame synchronization signal transmission module in a case where the input interface module is not connected with the synchronization line;

a main control chip module, configured to output the master clock signal to the master clock signal transmission module and output the frame synchronization signal to the frame synchronization signal transmission module in a case where the detection signal is received;

a master clock signal transmission module, configured to transmit the master clock signal input by the input interface module to the output interface module in a case where the first control signal is received; transmit the master clock signal generated by the main control chip module to the output interface module in a case where the second control signal is received;

a frame synchronization signal transmission module, configured to transmit the frame synchronization signal input by the input interface module to the output interface module in a case where the first control signal is received; transmit the frame synchronization signal generated by the main control chip module to the output interface module in a case where the second control signal is received;

a camera module, configured to perform picture capture based on the frame synchronization signal and the master clock signal; and

the output interface module, configured to output the master clock signal or the frame synchronization signal.

The present disclosure provides a synchronization circuit arranged within each camera of a distributed camera system, including:

an input interface module, configured to input a synchronization instruction signal;

a detection control module, configured to output a first control signal to a synchronization instruction signal transmission module in a case where the input interface module is connected with a synchronization line; output a detection signal to a main control chip module, and output a second control signal to the synchronization instruction signal transmission module in a case where the input interface module is not connected with the synchronization line;

the main control chip module, configured to output the synchronization instruction signal to the synchronization instruction signal transmission module in a case where the detection signal is received;

the synchronization instruction signal transmission module, configured to transmit the synchronization instruction signal input by the input interface module to the output interface module in a case where the first control signal is received; the synchronization instruction signal transmission module is configured to transmit the synchronization instruction signal generated by the main control chip module to the output interface module in a case where the second control signal is received;

the output interface module, configured to output the synchronization instruction signal to a succeeding camera;

an instruction module, configured to generate a control instruction signal and execute the control instruction signal; wherein the control instruction signal corresponds to the synchronization instruction signal;

an information transmission module, connected between the input interface module and the output interface module of two adjacent cameras, the information transmission module being configured to transmit the control instruction signal;

in a case where the input interface module is connected with the synchronization line, the instruction module receives a control instruction signal from a preceding camera through the information transmission module, executes the control instruction signal based on a corresponding synchronization instruction signal, and sends the control instruction signal to a succeeding camera through the information transmission module; and

in a case where the input interface module is not connected with the synchronization line, the instruction module generates the control instruction signal, executes the control instruction signal based on the corresponding synchronization instruction signal, and sends the control instruction signal to the succeeding camera through the information transmission module.

The present disclosure further provides a distributed camera system, including:

a plurality of cameras, each internally provided with a synchronization circuit in one-to-one correspondence, wherein one of the cameras serves as a master camera, the rest of the cameras are slave cameras, the operating mode of the master camera is a master mode, and the operating mode of the slave cameras is a slave mode;

a synchronization line, with one end connected with an output interface module of the master camera and the other end connected with an input interface module of the slave camera, or connected between the input interface module and the output interface module of two adjacent slave cameras for transmitting a control instruction signal, a synchronization instruction signal, a master clock signal, and/or a frame synchronization signal;

wherein each camera generates a picture for subsequent picture synchronized presentation based on the master clock signal and the frame synchronization signal; each camera performs synchronization control of all cameras based on the control instruction signal and the synchronization instruction signal.

Compared with the prior art, this disclosure has the following beneficial effects: this disclosure provides a synchronization circuit, which includes an input interface module, a detection control module, a main control chip module, a master clock signal transmission module, a frame synchronization signal transmission module, and an output interface module. Driven by a second control signal, the master clock signal transmission module transmits the master clock signal input from the input interface module to the output interface module, while the frame synchronization signal transmission module transmits the frame synchronization signal input from the input interface module to the output interface module.

Driven by the first control signal, the master clock signal transmission module transmits the master clock signal generated by the main control chip module to the output interface module, while the frame synchronization signal transmission module transmits the frame synchronization signal generated by the main control chip module to the output interface module. A plurality of cameras provided with the synchronization circuits can form a distributed camera system, where the master clock signals and frame synchronization signals of the image sensors inside all cameras are generated by a camera operating in a master mode. As a result, all cameras achieve an extremely high standard of frame synchronization in image generation, enhancing the picture synchronization of different cameras. This effectively resolves the technical problem of poor image synchronization among cameras in existing distributed camera systems.

### BRIEF DESCRIPTION OF DRAWINGS

FIG. 1 is a block diagram of a first embodiment of a synchronization circuit of the present disclosure.

FIG. 2 is a circuit diagram of an input interface module of the first embodiment of the synchronization circuit of the present disclosure.

FIG. 3 is a circuit diagram of an output interface module of the first embodiment of the synchronization circuit of the present disclosure.

FIG. 4 is a circuit diagram of a detection control module of the first embodiment of the synchronization circuit of the present disclosure.

FIG. 5 is a circuit diagram of a master clock signal transmission module of the first embodiment of the synchronization circuit of the present disclosure.

FIG. 6 is a circuit diagram of a frame synchronization signal transmission module of the first embodiment of the synchronization circuit of the present disclosure.

FIG. 7 is a block diagram of a second embodiment of the synchronization circuit of the present disclosure.

FIG. 8 is a circuit diagram of a synchronization instruction signal transmission module of the synchronization circuit of the present disclosure.

FIG. 9 is a circuit diagram of an information transmission module of the synchronization circuit of the present disclosure.

FIG. 10 is a structural schematic diagram of the synchronization circuit of the distributed camera system of the present disclosure.

In the figures, 10, synchronization circuit; 11, input interface module; 12, detection control module; 13, main control chip module; 14, synchronization instruction signal transmission module; 15, master clock signal transmission module; 16, frame synchronization signal transmission module; 17, output interface module; 18, information transmission module; 181, instruction module; 19, power supply.

### DETAILED DESCRIPTION OF THE INVENTION

The technical solutions in the embodiments of the present disclosure will be clearly and completely described below in conjunction with the accompanying drawings in the embodiments of the present disclosure, it is obvious that the described embodiments are only a part of the embodiments of the present disclosure, rather than all of the embodiments. Based on the embodiments in the present disclosure, all other embodiments obtained by those skilled in the art without making inventive labor, belong to the scope of protection of the present disclosure.

Directional terms, such as “upper”, “lower”, “front”, “back”, “left”, “right”, “inner”, “outer”, “side”, “top”, and “bottom”, are merely directional terms used with reference to the orientations of the drawings, and are intended to illustrate and understand the present disclosure, and are not intended to limit the present disclosure.

The words “first” and “second” in the terminology of the present disclosure are for descriptive purposes only, and are not to be understood as indicating or implying relative importance, and are not intended to limit the order of precedence.

In the figures, units that are structurally similar are indicated by the same reference numerals.

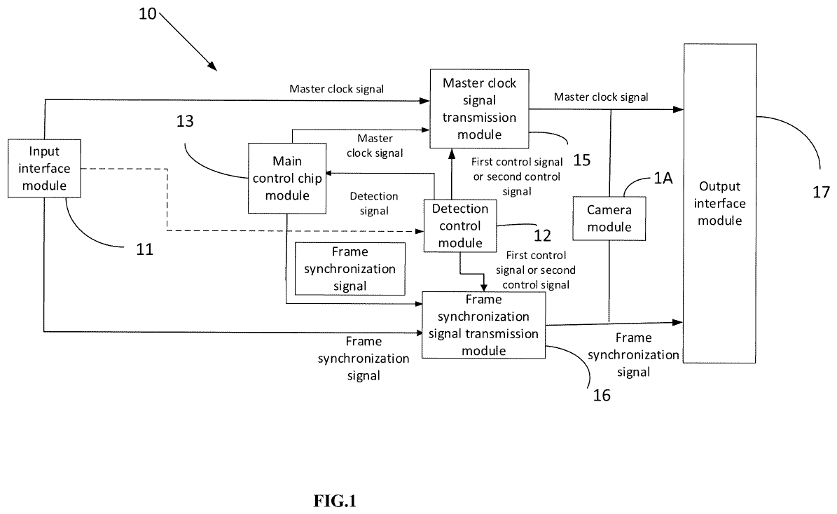

Referring to FIG. 1, the following is a detailed description of a first embodiment of the present disclosure:

the present disclosure provides a synchronization circuit 10 that is arranged within the camera. The synchronization circuit 10 includes an input interface module 11, a detection control module 12, a main control chip module 13, a master clock signal transmission module 15, a frame synchronization signal transmission module 16, an output interface module 17, and a camera module 1A.

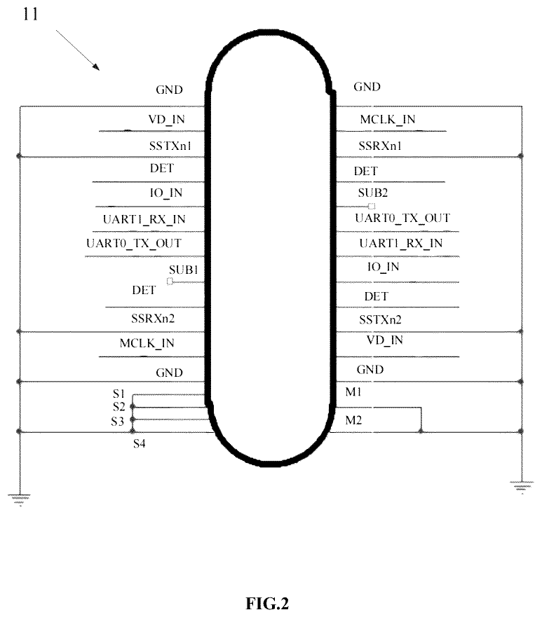

Please refer to FIG. 1 and FIG. 2, the input interface module 11 is configured to input a master clock signal or a frame synchronization signal, both of which originate from a preceding camera. The master clock signal can be generated by an image sensor inside the camera. Moreover, the detection control module 12 can output a first control signal OE1 and a second control signal OE2. In a case where the input interface module 11 is connected with a synchronization line, the detection control module 12 outputs the first control signal OE1 to the master clock signal transmission module 15 and the frame synchronization signal transmission module 16. In a case where the input interface module 11 is not connected with the synchronization line, the detection control module 12 outputs a low-level detection signal to the main control chip module 13 and outputs the second control signal OE2 to the master clock signal transmission module 15 and the frame synchronization signal transmission module 16. The camera module 1A performs image capture based on the master clock signal output by the master clock signal transmission module 15 and the frame synchronization signal output by the frame synchronization signal transmission module 16.

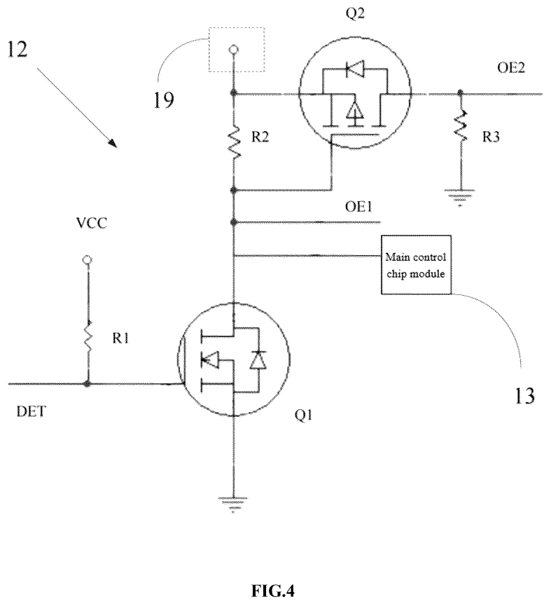

Please refer to FIGS. 2 and 4, the input interface module 11 includes a DET pin, and the detection control module 12 includes a first MOSFET Q1 and a second MOSFET Q2. The gate of the first MOSFET Q1 is connected with the DET pin of the input interface module 11 and a power supply VCC, and the drain of the first MOSFET Q1 is connected with the gate of the second MOSFET Q2. The source of the first MOSFET Q1 is grounded, and the source of the second MOSFET Q2 is connected with the gate. The source of the second MOSFET Q2 is further connected with a power supply 19, the drain of the first MOSFET Q1 is further configured to output the detection signal and the first control signal OE1, the drain of the second MOSFET Q2 is configured to output the second control signal OE2.

Please refer to FIGS. 2, 5 and 6, the input interface module 11 includes a VD_IN pin and a MCLK_IN pin. The MCLK_IN pin is connected with the third input pin U54 of the master clock signal transmission chip U5, and the MCLK_IN pin is connected with the third input pin U64 of the master clock signal transmission chip U6. The VD_IN pin is connected with the fifth input pin U34 of the frame synchronization signal transmission chip U3, and the VD_IN pin is connected with the fifth input pin U44 of the frame synchronization signal transmission chip U4. The VD_IN pin is configured to input the frame synchronization signal from the preceding camera, and the MCLK_IN pin is configured to input the master clock signal from the preceding camera.

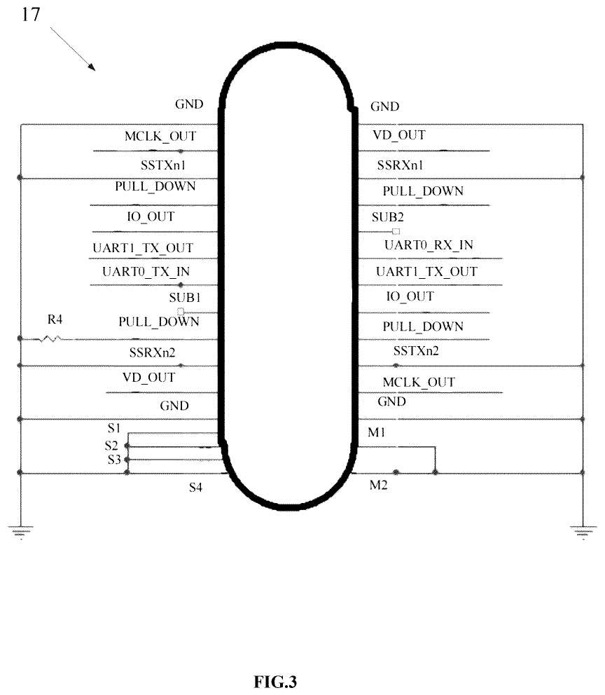

Please refer to FIG. 1, FIG. 3 and FIG. 4, the detection control module 12 further includes a first resistor R1, a second resistor R2 and a third resistor R3, and one end of the first resistor R1 is connected with the gate of the first MOSFET Q1.The other end of the first resistor R1 is connected with the power supply VCC, and the resistance value of the first resistor R1 is 100 KΩ. One end of the second resistor R2 is connected with the source of the second MOSFET Q2, the other end of the second resistor R2 is connected with the gate of the second MOSFET Q2, and the resistance value of the second resistor R2 is 10 KΩ. One end of the third resistor R3 is connected with the drain of the second MOSFET Q2, the other end of the third resistor R3 is grounded, and the resistance value of the third resistor R3 is 10 KΩ. The output interface module 17 includes a PULL_DOWN pin and a fourth resistor R4, one end of the fourth resistor R4 is connected with the PULL_DOWN pin. The fourth resistor R4 is a pull-down resistor, therefore, after the input interface module 11 and the output interface module 17 of two adjacent cameras are connected through the synchronization line, the DET pin of the input interface module 11 of the preceding camera can be pulled down to a low level by the fourth resistor R4 of the output interface module 17 of the succeeding camera.

Each camera can operate as either a master or a slave device, with its current operating mode (master or slave) determined by the connection configuration of the synchronization line. The camera is equipped with a main control chip module 13 that identifies the operating mode-master or slave-based on detection signals. In a case where the input interface module 11 is connected with the synchronization line, the detection control module 12 outputs a high-level detection signal, prompting the main control chip module 13 to recognize the camera as operating in the slave mode. In a case where the input interface module 11 is not connected with the synchronization line, the detection control module 12 outputs a low-level detection signal, prompting the main control chip module 13 to recognize the camera as operating in the master mode.

Please refer to FIG. 2, FIG. 3 and FIG. 4, if the input interface module 11 of the camera is not connected with the synchronization line, since the first resistor R1 can be pulled up to the power supply, causing the gate of the first MOSFET Q1 to receive a high-level signal (the first MOSFET Q1 is turned on). Thus, the drain of the first MOSFET Q1 outputs a low-level detection signal, and based on the low-level detection signal, the main control chip module 13 can recognize the operating mode of the camera as the master mode. If the input interface module 11 of the camera is connected with the synchronization line, the input interface module 11 can be connected with the output interface module 17 of another camera via the synchronization line. At this time, the DET pin of the input interface module 11 is connected with the PULL_DOWN pin of the output interface module 17 of another camera. Thus, the DET pin of the input interface module 11 is pulled down to a low level by the fourth resistor R4 of another camera through the synchronization line. This causes the gate of the first MOSFET Q1 to receive a low-level signal. Further, the drain of the first MOSFET Q1 may output a high-level detection signal (the first MOSFET Q1 is turned off). Based on the high-level detection signal, the main control chip module 13 can recognize the operating mode of the camera as the slave mode. In a case where the low-level detection signal is received, the main control chip module 13 outputs the master clock signal to the master clock signal transmission module 15. In addition, the main control chip module 13 outputs the frame synchronization signal to the frame synchronization signal transmission module 16.

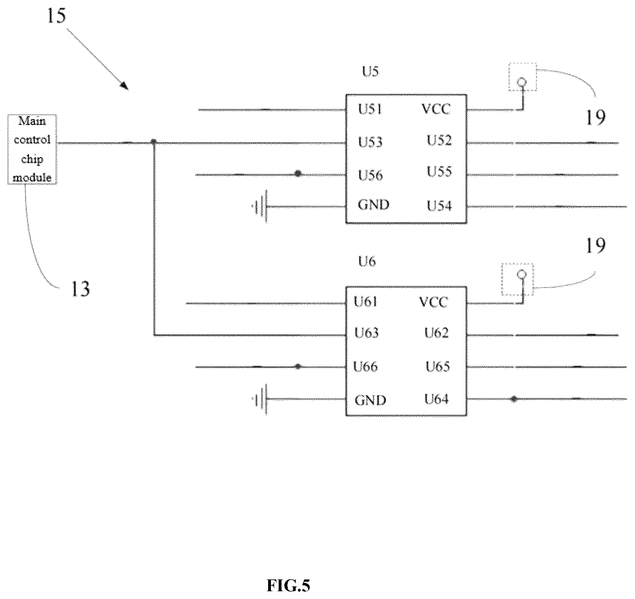

Please refer to FIGS. 4 and 5, the master clock signal transmission module 15 includes master clock signal transmission chips, and the master clock signal transmission chip is a fast logic chip, and the model of the master clock signal transmission chip is SN74IVC2G126. The number of the master clock signal transmission chips is two, and the master clock signal transmission chips include a first master clock signal transmission chip U5 and a second master clock signal transmission chip U6. Wherein, the first master clock signal transmission chip U5 and the second master clock signal transmission chip U6 are two identical chips. In a case where the first control signal OE1 is received, the master clock signal transmission module 15 transmits the master clock signal input from the input interface module 11 to the output interface module 17. In a case where the second control signal OE2 is received, the master clock signal transmission module 15 transmits the master clock signal generated by the main control chip module 13 to the output interface module 17.

Please refer to FIGS. 4 and 5, the master clock signal transmission chip U5 includes a third control pin U51 and a fourth control pin U52, and the master clock signal transmission chip U6 includes a third control pin U61 and a fourth control pin U62. The third control pin U51 and the third control pin U61 are connected with the drain of the second MOSFET Q2, the third control pin U61and the third control pin U51 are configured to receive the second control signal OE2. The fourth control pin U52 and the fourth control pin U62 are connected with the drain of the first MOSFET Q1, the fourth control pin U62 and the fourth control pin U52 are configured to receive the first control signal OE1.

Please refer to FIGS. 2, 4 and 5, the master clock signal transmission chip U5 further includes a third input pin U54, a fourth input pin U53 and a second output pin U55. The master clock signal transmission chip U6 further includes a third input pin U64, a fourth input pin U63 and a second output pin U65, the input interface module 11 includes an MCLK_IN pin. The third input pin U54 and the third input pin U64 are connected with the MCLK_IN pin of the input interface module 11, the third input pin U54 and the third input pin U64 are configured to receive the master clock signal input by the input interface module 11. The fourth input pin U53 and the fourth input pin U63 are connected with the main control chip module 13, the fourth input pin U53 and the fourth input pin U63 are configured to input the master clock signal generated by the main control chip module 13. The second output pin U55 and the second output pin U65 are connected with the output interface module 17, the second output pin U55 and the second output pin U65 are configured to output the master clock signal. The master clock signal transmission chip includes a VCC pin connected with the power supply 19 and a GND pin connected with the ground.

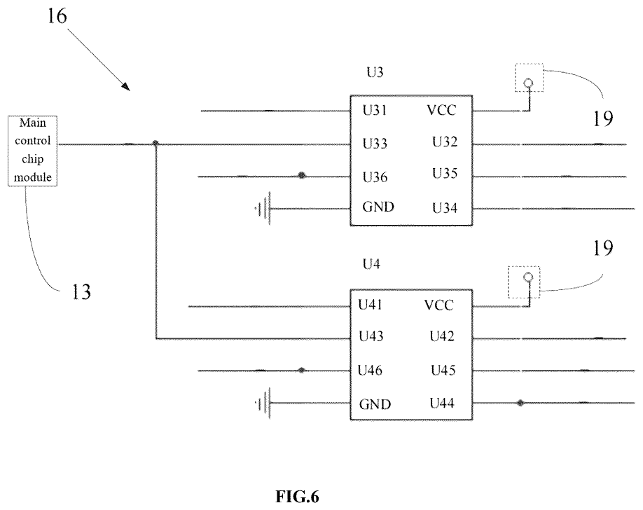

Please refer to FIGS. 4 and 6, the frame synchronization signal transmission module 16 includes frame synchronization signal transmission chips, the frame synchronization signal transmission chip is a fast logic chip, and a model of the frame synchronization signal transmission chip is SN74IVC2G126. The number of the frame synchronization signal transmission chips is two, and the frame synchronization signal transmission chips include a first frame synchronization signal transmission chip U3 and a second frame synchronization signal transmission chip U4. Wherein, the first frame synchronization signal transmission chip U3 and the second frame synchronization signal transmission chip U4 are two identical chips. In a case where the first control signal OE1 is received, the frame synchronization signal transmission module 16 transmits the frame synchronization signal input by the input interface module 11 to the output interface module 17. In a case where the second control signal OE2 is received, the frame synchronization signal transmission module 16 transmits the frame synchronization signal generated by the main control chip module 13 to the output interface module 17.

Please refer to FIGS. 4 and 6, the frame synchronization signal transmission chip U3 includes a fifth control pin U31 and a sixth control pin U32, and the frame synchronization signal transmission chip U4 includes a fifth control pin U41 and a sixth control pin U42. The fifth control pin U31 and the fifth control pin U41 are connected with the drain of the second MOSFET Q2, the fifth control pin U31and the fifth control pin U41 are configured to receive the second control signal OE2. The sixth control pin U32 and the sixth control pin U42 are connected with the drain of the first MOSFET Q1, the sixth control pin U32 and the fourth control pin U42 are configured to receive the first control signal OE1.

Please refer to FIG. 2, FIG. 4 and FIG. 6, the frame synchronization signal transmission chip U3 further includes a fifth input pin U34, a sixth input pin U33 and a third output pin U35. The frame synchronization signal transmission chip U4 further includes a fifth input pin U44, a sixth input pin U43 and a third output pin U45, and the input interface module 11 includes a VD_IN pin. The fifth input pin U34, the fifth input pin U44 are each connected with the VD_IN pin of the input interface module 11, and the fifth input pin U34 and the fifth input pin U44 are configured to receive the frame synchronization signal input by the input interface module 11. The sixth input pin U33 and the sixth input pin U43 are both connected with the main control chip module 13, the sixth input pin U33 and the sixth input pin U43 are configured to input a frame synchronization signal generated by the main control chip module 13. The third output pin U35 and the third output pin U45 are both connected with the output interface module 17, the third output pin U35 and the third output pin U45 are configured to output a frame synchronization signal. The frame synchronization signal transmission chip includes a VCC pin connected with the power supply 19 and a GND pin connected with the ground.

Please refer to FIGS. 4 and 5, in a case where the camera operates in the master mode, the third control pin U51 and the third control pin U61 may receive the second control signal OE2. Wherein, the third control pin U51 and the third control pin U61 receive a high-level signal. At this time, the fourth input pin U53 and the fourth input pin U63 may input the master clock signal generated by the main control chip module 13. Further, the second output pin U55 and the second output pin U65 may output the master clock signal to the output interface module 17. In a case where the camera operates in the slave mode, the fourth control pin U52 and the fourth control pin U62 may receive the first control signal OE1. Wherein, the fourth control pin U52 and the fourth control pin U62 receive a high-level signal. At this time, the third input pin U54 and the third input pin U64 are configured to receive the master clock signal input by the input interface module 11. Further, the second output pin U55 and the second output pin U65 may output the master clock signal to the output interface module 17. Thus, the synchronization circuit 10 can achieve fast synchronization of master clock signal transmission among a plurality of cameras.

Please refer to FIGS. 4 and 6, in a case where the camera works in the master mode, the fifth control pin U31 and the fifth control pin U41 may receive the second control signal OE2. Wherein, the fifth control pin U31 and the fifth control pin U41 receive a high-level signal. At this time, the sixth input pin U33 and the sixth input pin U43 may input the frame synchronization signal generated by the main control chip module 13. Further, the third output pin U35 and the third output pin U45 may output the frame synchronization signal to the output interface module 17. The sixth control pin may receive a first control signal OE1 in a case where the camera is operating in the slave mode. Wherein, the sixth control pin U32 and the sixth control pin U42 receive a high-level signal. At this time, the fifth input pin U34 and the fifth input pin U44 are configured to receive the frame synchronization signal input by the input interface module 11. Further, the third output pin U35 and the third output pin U45 may output the frame synchronization signal to the output interface module 17. Thus, the synchronization circuit 10 enables fast synchronization of frame synchronization signal transmission among a plurality of cameras. By selecting a fast logic chip, the synchronization circuit 10 can achieve very low latency frame synchronization between two adjacent cameras. The present circuit selects the SN741VC2G126 logic chip so that the synchronization circuit 10 achieves frame synchronization within 8 ns of the camera modules 1A of two adjacent cameras.

Please refer to FIG. 3, the output interface module 17 is configured to output a master clock signal or a frame synchronization signal to the succeeding camera. The output interface module 17 includes a VD_OUT pin and a MCLK_OUT pin. The MCLK_OUT pin is connected with the second output pin, and the VD_OUT pin is connected with the third output pin. The IO_OUT pin is configured to output a synchronization instruction signal to the succeeding camera, the MCLK_OUT pin is configured to output a master clock signal to the succeeding camera, and the VD_OUT pin is configured to output a frame synchronization signal to the succeeding camera. A plurality of cameras provided with the synchronization circuit may constitute a distributed camera system, the master clock signal and the frame synchronization signal of the image sensors of the camera modules 1A of all the cameras are generated by the camera of the master mode, so that the frame synchronicity of the images generated by all the cameras reaches a very high standard, and the number of image frames output by all the cameras is strictly the same. In a distributed system of 100 digital cameras, the time difference between image frames can be made to within 0.8 us. Further, using a standard USB 3.0 type-c to type-c line for synchronization reduces both the cost of synchronization lines and the complexity of distributed networking for a plurality of cameras.

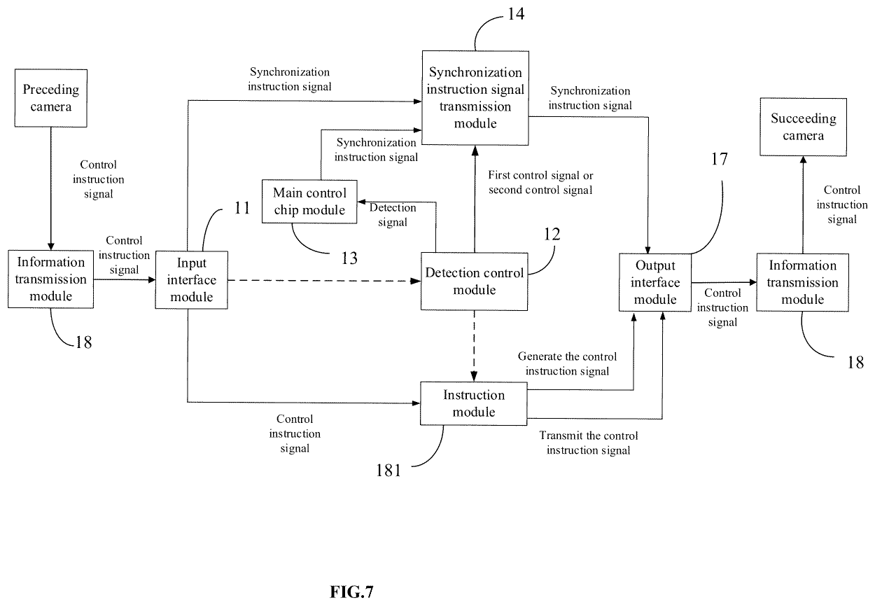

Please refer to FIG. 7, the following is a detailed description of a second embodiment of the present disclosure:

The synchronization circuit 10 further includes an information transmission module 18 and an instruction module 181, and the instruction module 181 is configured to generate a control instruction signal and execute the control instruction signal. The information transmission module 18 is connected between the input interface module 11 and the output interface module 17 of two adjacent cameras, the information transmission module 18 is configured to transmit the control instruction signal.

In a case where the input interface module 11 is connected with the synchronization line, i.e., the camera is in the slave mode, the instruction module 181 receives the control instruction signal from the preceding camera through the information transmission module 18 and executes the control instruction signal. Subsequently, the instruction module 181 sends the control instruction signal to the succeeding camera through the information transmission module 18. In a case where the synchronization line is not connected with the input interface module, i.e., the camera is in the master mode, the instruction module 181 generates the control instruction signal and executes the control instruction signal. Subsequently, the instruction module 181 sends the control instruction signal to the succeeding camera through the information transmission module 18. Thus, the camera in the master mode can control all cameras in the slave mode through the control instruction signal.

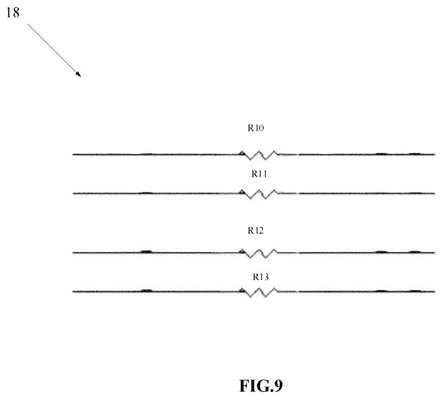

Please refer to FIG. 2, FIG. 3 and FIG. 9, the information transmission module 18 includes a fifth resistor R10, a sixth resistor R11, a seventh resistor R12, and an eighth resistor R13. The input interface module 11 includes a UARTO_TX pin, a UARTO_RX pin, a UARTI_TX pin, and a UARTI_RX pin, and the output interface module 17 includes a UARTO_TX_OUT pin, a UARTO_RX_IN pin, a UARTI_TX_OUT pin, and a UARTI_RX_IN pin. One end of the fifth resistor R10 is connected with the UARTO_TX pin, the other end of the fifth resistor R10 is connected with the UARTO_TX_OUT pin. One end of the sixth resistor R11 is connected with the UARTO_RX pin, the other end of the sixth resistor R11 is connected with the UARTO_RX_IN pin. One end of the seventh resistor R12 is connected with the UARTI_TX pin, the other end of the seventh resistor R12 is connected with the UARTI_RX_IN pin. One end of the eighth resistor R13 is connected with the UARTO_TX pin, the other end of the eighth resistor R13 is connected with the UARTI_RX_IN pin.

Wherein the control instruction signal may be numbering information. In a case where the camera is in the master mode, the instruction module of the camera in the master mode performs a numbering operation on the camera. Moreover, the instruction module of the camera in the master mode may further generate numbering information and transmit the numbering information to the succeeding camera. In a case where the camera is in the slave mode, the camera receives the numbering information generated by the preceding camera through the information transmission module 18, and the instruction module of the camera can perform a numbering operation on the camera based on the numbering information. Moreover, the instruction module of the camera may generate the numbering information and transmit the numbering information to the succeeding camera.

For example, networked cameras may be automatically numbered sequentially. The camera in the master mode assigns itself the number 0 and transmits the number 1 to the adjacent slave-mode camera via the information transmission module 18. The subsequent master-mode camera assigns itself the number 1 and transmits the number 2 to the next adjacent slave-mode camera via the information transmission module 18. The next adjacent slave-mode camera assigns itself the number 2 . . . and so on. This automatic sequential numbering significantly simplifies system maintenance tasks.

Further, the synchronization circuit 10 further includes a synchronization instruction signal transmission module 14. The input interface module 11 is configured to input a synchronization instruction signal, and in a case where the detection signal is received, the main control chip module 13 outputs the synchronization instruction signal to the synchronization instruction signal transmission module 14. Wherein the control instruction signal corresponds to the synchronization instruction signal. Thus, based on the synchronization instruction signal, all cameras can execute the control instruction signal at the same time. Therefore, even if a plurality of cameras need to execute the control instruction signal, a time delay phenomenon does not occur. In a case where the input interface module 11 is connected with the synchronization line, the detection control module 12 further outputs the first control signal OE1 to the synchronization instruction signal transmission module 14. In a case where the input interface providing module 11 is not connected with the synchronization line, the detection control module 12 outputs the second control signal OE2 to the synchronization instruction signal transmission module 14.

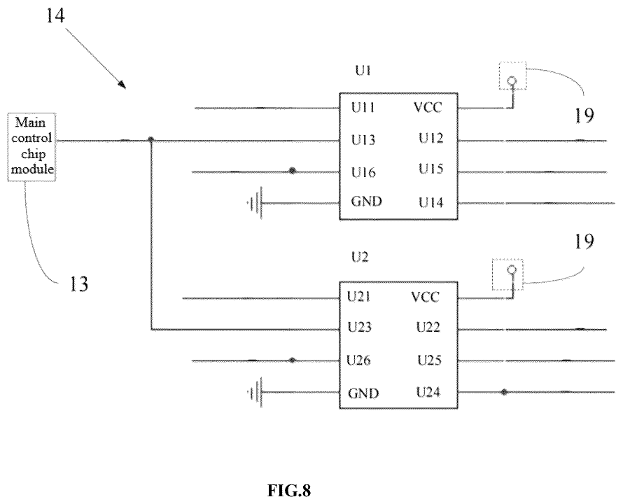

Please refer to FIGS. 7 and 8, the synchronization instruction signal transmission module 14 includes synchronization instruction signal transmission chips, and the synchronization instruction signal transmission chip is a fast logic chip, and a model of the synchronization instruction signal transmission chip is SN74IVC2G126. The number of the synchronization instruction signal transmission chips is two, and the synchronization instruction signal transmission chips include a first synchronization instruction signal transmission chip U1 and a second synchronization instruction signal transmission chip U2, wherein the first synchronization instruction signal transmission chip U1 and the second synchronization instruction signal transmission chip U2 are two identical chips. In a case where the first control signal OE1 is received, the synchronization instruction signal transmission module 14 may transmit the synchronization instruction signal input from the input interface module 11 to the output interface module 17. In a case where the second control signal OE2 is received, the synchronization instruction signal transmission module 14 transmits the synchronization instruction signal generated by the main control chip module 13 to the output interface module 17.

Please refer to FIG. 2, FIG. 4 and FIG. 9, the input interface module 11 includes a VD_IN pin, an IO_IN pin, and a MCLK_IN pin, and the IO_IN pin is configured to input the synchronization instruction signal from the adjacent camera. The synchronization instruction signal transmission chip U1 includes a first control pin U11 and a second control pin U12, and the synchronization instruction signal transmission chip U2 includes a first control pin U21 and a second control pin U22. The first control pin U11 and the first control pin U21 are both connected with the drain of the second MOSFET Q2. The first control pin U11 and the first control pin U21 are configured to receive the second control signal OE2, the second control pin U12 and the second control pin U22 are connected with the drain of the first MOSFET Q1, the second control pin U12 and the second control pin U22 are configured to receive the first control signal OE1.

Please refer to FIGS. 2 and 8, the synchronization instruction signal transmission chip U1 further includes a first input pin U14, a second input pin U13 and a first output pin U15, the synchronization instruction signal transmission chip U2 further includes a first input pin U24, a second input pin U23 and a first output pin U25. The input interface module 11 includes an IO_IN pin, and the first input pin U14, the first input pin U24 are each connected with the IO_IN pin of the input interface module 11. The first input pin U14 and the first input pin U24 are configured to receive the synchronization instruction signal input by the input interface module 11, the second input pin U13 and the second input pin U23 are each connected with the main control chip module 13, and the second input pin U13 and the second input pin U23 are configured to input the synchronization instruction signal generated by the main control chip module 13. The first output pin U15 and the first output pin U25 are connected with the output interface module 17, the first output pin U15 and the first output pin U25 are configured to output the synchronization instruction signal. The synchronization instruction signal transmission chip includes a VCC pin and a GND pin, the VCC pin is connected with the power supply 19, and the GND pin is grounded.

Please refer to FIG. 2, FIG. 3 and FIG. 8, in a case where the camera works in the master mode, the first control pin U11 and the first control pin U21 may receive the second control signal OE2. Wherein, the first control pin U11 and the first control pin U21 receive a high-level signal. At this time, the second input pin U13 and the second input pin U23 can input the synchronization instruction signal generated by the main control chip module 13. Further, the first output pin U15and the first output pin U25 may output the synchronization instruction signal to the output interface module 17. In a case where the camera operates in the slave mode, the second control pin U12 and the second control pin U22 may receive the first control signal OE1. Wherein, the second control pin U12 and the second control pin U22 receive a high-level signal. At this time, the first input pin U14 and the first input pin U24 are configured to receive the synchronization instruction signal input by the input interface module 11. Further, the first output pin U15 and the first output pin U25 may output the synchronization instruction signal to the output interface module 17. The output interface module 17 includes an IO_OUT pin connected with the first output pin for outputting the synchronization instruction signal to an adjacent external camera.

Wherein, in a case where the camera is in the slave mode, the synchronization instruction signal transmission module 14 transmits the synchronization instruction signal input from the input interface module 11 to the output interface module 17 under the driving of the first control signal OE1. In a case where the camera is in the master mode, the synchronization instruction signal transmission module 14 transmits the synchronization instruction signal generated by the main control chip module 13 to the output interface module 17 under the driving of the second control signal OE2. Therefore, the synchronization circuit 10 can achieve fast synchronization of synchronization instruction signal transmission among a plurality of cameras.

The control instruction signal may be a shutter speed signal, and executing the control instruction signal based on the synchronization instruction signal may achieve shutter speed synchronization. For the shutter speed signal, the master-mode camera calculates the appropriate shutter speed and transmits shutter speed signal to all slave-mode cameras via its information transmission module 18. Thus, all slave-mode cameras share the same shutter speed as the master-mode camera. That is, the master sends its own shutter speed to the slave in real time, and the slave sends the shutter speed parameter received from the master to its image sensor, so that the whole system can always use the same shutter speed. The control instruction signal may be a time signal, and executing the control instruction signal based on the synchronization instruction signal may achieve time synchronization. That is, the master-mode camera sends its own system time to the slave-mode camera so that the whole system can use the same system time all the time. The control instruction signal may be a task signal, and executing the control instruction signal based on the synchronization instruction signal may achieve task synchronization. For example, the master-mode camera sends a task signal to the slave-mode camera, and all cameras of the whole system can start recording simultaneously or stop recording simultaneously. Automatic numbering can take effect in real time. As for the shutter speed signal, time signal, and task signal, the control instruction can be sent first, and then the master-mode camera can control all the other cameras to trigger and execute simultaneously.

The present embodiment provides a synchronization circuit 10 that is arranged within each camera of the distributed camera system. In a case where the input interface module 11 is connected with the synchronization line, i.e., the camera is in the slave mode. The detection control module 12 outputs the first control signal OE1 to the master clock signal transmission module 15 and the frame synchronization signal transmission module 16. In a case where the input interface module 11 is not connected with the synchronization line, i.e., the camera is in the master mode. The detection control module 12 outputs a low-level detection signal to the main control chip module 13. In addition, the detection control module 12 outputs the second control signal OE2 to the master clock signal transmission module 15 and the frame synchronization signal transmission module 16.

In a case where the first control signal OE1 is received, the master clock signal transmission module 15 transmits the master clock signal input from the input interface module 11 to the output interface module 17, and the frame synchronization signal transmission module 16 transmits the frame synchronization signal input from the input interface module 11 to the output interface module 17. In a case where the second control signal OE2 is received, the master clock signal transmission module 15 transmits the master clock signal generated by the main control chip module 13 to the output interface module 17, and the frame synchronization signal transmission module 16 transmits the frame synchronization signal generated by the main control chip module 13 to the output interface module 17. Further, the output interface module 17 may output a master clock signal or a frame synchronization signal.

Further, the synchronization circuit 10 further includes an information transmission module 18 and an instruction module 181. The instruction module 181 is configured to generate a control instruction signal and execute the control instruction signal, and the information transmission module 18 is connected between the input interface module and the output interface module of two adjacent cameras, and the information transmission module 18 is configured to transmit the control instruction signal.

In a case where the input interface module 11 is connected with the synchronization line, i.e., the camera is in the slave mode. The instruction module 181 receives the control instruction signal from the preceding camera through the information transmission module 18 and executes the control instruction signal, and the instruction module 181 may further send the control instruction signal to the succeeding camera through the information transmission module 18. In a case where the input interface module 11 is not connected with the synchronization line, i.e., the camera is in the master mode. The instruction module 181 generates a control instruction signal and executes the control instruction signal, the instruction module 181 sends the control instruction signal to the succeeding camera through the information transmission module 18.

The synchronization circuit 10 further includes a synchronization instruction signal transmission module 14, and in a case where the input interface module 11 is connected with the synchronization line, the detection control module outputs the first control signal OE1 to the synchronization instruction signal transmission module 14. In a case where the synchronization line is not connected with the input interface module 11, the detection control module 12 outputs a low-level detection signal to the main control chip module 13, and the detection control module 12 outputs the second control signal OE2 to the synchronization instruction signal transmission module 14. In a case where the low-level detection signal is received, the main control chip module 13 outputs a synchronization instruction signal to the synchronization instruction signal transmission module 14. Wherein the control instruction signal corresponds to the synchronization instruction signal. Thus, in a case where the first control signal OE1 is received, the synchronization instruction signal transmission module 14 transmits the synchronization instruction signal input by the input interface module 11 to the output interface module 17. In a case where the second control signal OE2 is received, the synchronization instruction signal transmission module transmits the synchronization instruction signal generated by the main control chip module 13 to the output interface module 17.

Accordingly, in the third embodiment of the present disclosure, each camera can generate a picture based on the master clock signal and the frame synchronization signal so that subsequent pictures can be displayed synchronously. Since the master clock signal corresponds to the frame synchronization signal, the frame synchronicity of the images generated by all cameras reaches a very high standard. In addition, each camera performs synchronous control of all cameras based on the control instruction signal and the synchronization instruction signal. Based on the synchronization instruction signal, the camera in the master mode can control all cameras to trigger and execute the control instruction signal simultaneously. Consequently, no delay occurs in a case where all cameras are performing tasks assigned by the master.

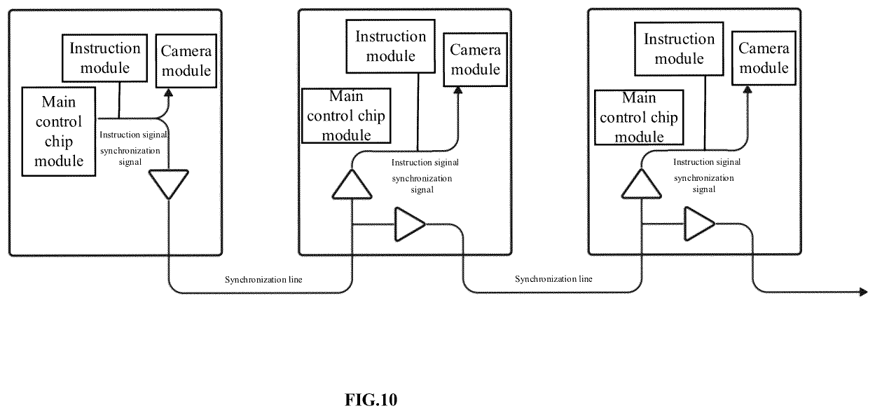

The present disclosure further includes a distributed camera system including a plurality of cameras and a synchronization line. Each camera is internally provided with the synchronization circuit described above in one-to-one correspondence, wherein one of the cameras serves as a master camera, the rest of the cameras are slave cameras, the operating mode of the master camera is a master mode, and the operating mode of the slave cameras is a slave mode. One end of the synchronization line is connected with the output interface module 17 of the master camera, and the other end of the synchronization line is connected with the input interface module 11 of the slave camera. Alternatively, the synchronization line may be connected between the input interface module 11 and the output interface module 17 of two adjacent slave cameras, and the synchronization line may be configured to transmit a control instruction signal, a synchronization instruction signal, a master clock signal or a frame synchronization signal. Wherein each camera generates a picture for subsequent picture synchronous presentation based on the master clock signal and the frame synchronization signal, and each camera performs synchronous control of all cameras based on the control instruction signal and the synchronization instruction signal. In particular, as shown in FIG. 10, wherein the synchronization signal includes a synchronization instruction signal, a master clock signal, and a frame synchronization signal, the instruction signal includes a control instruction signal.

The working principle of the present disclosure is that in a case where the input interface module 11 is not connected with the synchronization line, the detection control module 12 outputs a low-level detection signal. Then, the main control chip module 13 can recognize the operating mode of the camera as the master mode. Further, the main control chip module 13 may generate a master clock signal and a frame synchronization signal. Subsequently, the detection control module 12 outputs the second control signal OE2. The third control pin U51 and the third control pin U61 receive this second control signal OE2. Based on this second control signal OE2, the fourth input pin U53 and the fourth input pin U63 may input a master clock signal generated by the main control chip module 13. Further, the second output pin U55 and the second output pin U65 may output the master clock signal to the output interface module 17. Further, the fifth control pin U31 and the fifth control pin U41 of the frame synchronization signal transmission chip may receive the second control signal OE2. Based on this second control signal OE2, the sixth input pin U34 and the sixth input pin U44 can input a frame synchronization signal generated by the main control chip module 13. Further, the third output pin U35 and the third output pin U45 may output the frame synchronization signal to the output interface module 17. Since the output interface module 17 is connected with the succeeding camera through the synchronization line, the output interface module 17 can output the master clock signal or the frame synchronization signal to the succeeding camera.

Further, the instruction module 181 generates the control instruction signal. Meanwhile, based on the low-level detection signal, the main control chip module 13 can further generate a synchronization instruction signal. In addition, the first control pin U11 and the first control pin U21 each receive the second control signal OE2 output by the detection control module 12. Based on this second control signal OE2, the second input pin U13 and the second input pin U23 can input the synchronization instruction signal generated by the main control chip module 13. Besides, the control instruction signal corresponds to the synchronization instruction signal. Accordingly, the camera may execute the control instruction signal based on the synchronization instruction signal. Then, the first output pin U15 and the first output pin U25 may output the synchronization instruction signal to the output interface module 17. Further, the instruction module 181 sends the control instruction signal to the succeeding camera through the information transmission module 18.

In a case where the input interface module 11 is connected with the synchronization line, the input interface module 11 can input the master clock signal or the frame synchronization signal of the preceding camera. Further, the detection control module 12 may output a high-level detection signal. Then, the main control chip module 13 can recognize the operating mode of the camera as the slave mode. Subsequently, the detection control module 12 outputs a first control signal OE1. Moreover, the fourth control pin U52 and the fourth control pin U62 both receive the first control signal OE1. Based on this first control signal OE1, the third input pin U54 and the third input pin U64 may input a master clock signal from the input interface module 11. Further, the second output pin U55 and the second output pin U65 may output the master clock signal to the output interface module 17. Further, the sixth control pin U32 and the sixth control pin U42 may receive the first control signal OE1. Based on the first control signal OE1, the fifth input pin U34 and the fifth input pin U44 may input a frame synchronization signal from the input interface module 11. Further, the third output pin U35 and the third output pin U45 may output the frame synchronization signal to the output interface module 17. Further, the output interface module 17 may output the master clock signal or the frame synchronization signal to the succeeding camera.

Further, the instruction module 181 receives the control instruction signal from the preceding camera through the information transmission module 18. Meanwhile, the second control pin U21 and the second control pin U22 receive the first control signal OE1 output by the detection control module 12. Based on this first control signal OE1, the first input pin U14 and the first input pin U24 can input a synchronization instruction signal from the input interface module 11. In addition, the control instruction signal corresponds to the synchronization instruction signal. Accordingly, the camera may execute the control instruction signal based on the synchronization instruction signal. Subsequently, the first output pin U15 and the first output pin U25 may output the synchronization instruction signal to the output interface module 17. Further, the instruction module 181 may further send the control instruction signal to the succeeding camera through the information transmission module 18.

The present disclosure provides a synchronization circuit, and the synchronization circuit includes an input interface module, a detection control module, a main control chip module, a master clock signal transmission module, a frame synchronization signal transmission module, and an output interface module. The master clock signal transmission module transmits the master clock signal input from the input interface module to the output interface module, and the frame synchronization signal transmission module transmits the frame synchronization signal input from the input interface module to the output interface module under the driving of the second control signal.

The master clock signal transmission module transmits the synchronization instruction signal generated by the main control chip module to the output interface module and the frame synchronization signal transmission module transmits the frame synchronization signal generated by the main control chip module to the output interface module under the driving of the first control signal. A plurality of cameras provided with the synchronization circuits can form a distributed camera system, where the master clock signal and frame synchronization signal for the image sensors inside all cameras are generated by a camera operating in a master mode. As a result, all cameras achieve an extremely high standard of frame synchronization in image generation, enhancing the picture synchronization of different cameras. This effectively resolves the technical problem of poor image synchronization among cameras in existing distributed camera systems.

In view of the above, although the present disclosure has been described with reference to the preferred embodiments, it is not intended to limit the present disclosure. Various modifications and changes may be made by those skilled in the art without departing from the spirit and scope of the present disclosure.

Accordingly, the scope of the present disclosure is defined by the appended claims.

What is claimed is:

1. A synchronization circuit, arranged within each camera of a distributed camera system, comprising:
an input interface module, configured to input a master clock signal or a frame synchronization signal;
a detection control module, configured to output a first control signal to a master clock signal transmission module and a frame synchronization signal transmission module in a case where the input interface module is connected with a synchronization line; output a detection signal to a main control chip module, and output a second control signal to the master clock signal transmission module and the frame synchronization signal transmission module in a case where the input interface module is not connected with the synchronization line;
a main control chip module, configured to output the master clock signal to the master clock signal transmission module and output the frame synchronization signal to the frame synchronization signal transmission module in a case where the detection signal is received;
a master clock signal transmission module, configured to transmit the master clock signal input by the input interface module to the output interface module in a case where the first control signal is received; transmit the master clock signal generated by the main control chip module to the output interface module in a case where the second control signal is received;
a frame synchronization signal transmission module, configured to transmit the frame synchronization signal input by the input interface module to the output interface module in a case where the first control signal is received; transmit the frame synchronization signal generated by the main control chip module to the output interface module in a case where the second control signal is received;
a camera module, configured to perform picture capture based on the frame synchronization signal and the master clock signal; and
the output interface module, configured to output the master clock signal or the frame synchronization signal.

2. The synchronization circuit according to claim 1, wherein, in a case where the input interface module is connected with the synchronization line, the detection control module outputs the detection signal at a high level, the main control chip module recognizes the operating mode of the camera as a slave mode; in a case where the input interface module is not connected with the synchronization line, the detection control module outputs the detection signal at a low level, and the main control chip module recognizes the operating mode of the camera as a master mode.

3. The synchronization circuit according to claim 1, wherein, the detection control module comprises a first metal-oxide-semiconductor field-effect transistor (MOSFET) and a second MOSFET, a gate of the first MOSFET is connected with the input interface module and a power supply, a drain of the first MOSFET is connected with a gate of the second MOSFET, a source of the first MOSFET is grounded, a source of the second MOSFET is connected with the gate, the source of the second MOSFET is further connected with a power supply, the drain of the first MOSFET is configured to output the detection signal, the first control signal, and a drain of the second MOSFET is configured to output the second control signal.

4. The synchronization circuit according to claim 3, wherein, the master clock signal transmission module comprises master clock signal transmission chips, the master clock signal transmission chip comprises a third control pin and a fourth control pin, the third control pin is connected with the drain of the second MOSFET, the third control pin is configured to receive the second control signal, the fourth control pin is connected with the drain of the first MOSFET, and the fourth control pin is configured to receive the first control signal; and
the master clock signal transmission chip further comprises a third input pin, a fourth input pin and a second output pin, the third input pin is connected with the input interface module, the third input pin is configured to receive the master clock signal input by the input interface module, the fourth input pin is connected with the main control chip module, the fourth input pin is configured to input the master clock signal generated by the main control chip module, the second output pin is connected with the output interface module, and the second output pin is configured to output the master clock signal.

5. The synchronization circuit according to claim 4, wherein, the frame synchronization signal transmission module comprises frame synchronization signal transmission chips, the frame synchronization signal transmission chip comprises a fifth control pin and a sixth control pin, the fifth control pin is connected with the drain of the second MOSFET, the fifth control pin is configured to receive the second control signal, the sixth control pin is connected with the drain of the first MOSFET, the sixth control pin is configured to receive the first control signal; and
the frame synchronization signal transmission chip further comprises a fifth input pin, a sixth input pin and a third output pin, the fifth input pin is connected with the input interface module, the fifth input pin is configured to receive the frame synchronization signal input by the input interface module, the sixth input pin is connected with the main control chip module, the sixth input pin is configured to input the frame synchronization signal generated by the main control chip module, the third output pin is connected with the output interface module, and the third output pin is configured to output the frame synchronization signal.

6. The synchronization circuit according to claim 5, wherein, the master clock signal transmission chip is a fast logic chip, a model of the master clock signal transmission chip is SN741VC2G126; the frame synchronization signal transmission chip is a fast logic chip, and a model of the frame synchronization signal transmission chip is SN74IVC2G126.

7. The synchronization circuit according to claim 1, further comprising an information transmission module and an instruction module, wherein the instruction module is configured to generate a control instruction signal and execute the control instruction signal;
the information transmission module is connected between the input interface module and the output interface module of two adjacent cameras, and the information transmission module is configured to transmit the control instruction signal;
in a case where the input interface module is connected with the synchronization line, the instruction module receives the control instruction signal from the preceding camera through the information transmission module and executes the control instruction signal, the instruction module sends the control instruction signal to the succeeding camera through the information transmission module; and
in a case where the input interface module is not connected with the synchronization line, the instruction module generates the control instruction signal and executes the control instruction signal, the instruction module sends the control instruction signal to the succeeding camera through the information transmission module.

8. The synchronization circuit according to claim 7, wherein, the synchronization circuit further comprises a synchronization instruction signal transmission module, the input interface module is configured to input a synchronization instruction signal, the main control chip module is configured to, in a case where the detection signal is received, output the synchronization instruction signal to the synchronization instruction signal transmission module, the control instruction signal corresponds to the synchronization instruction signal, and the detection control module is further configured to output the first control signal to the synchronization instruction signal transmission module in a case where the input interface module is connected with the synchronization line; output the second control signal to the synchronization instruction signal transmission module in a case where the input interface module is not connected with the synchronization line; and
the synchronization instruction signal transmission module is configured to transmit the synchronization instruction signal input by the input interface module to the output interface module in a case where the first control signal is received; the synchronization instruction signal transmission module is configured to transmit the synchronization instruction signal generated by the main control chip module to the output interface module in a case where the second control signal is received.

9. The synchronization circuit according to claim 8, wherein, the synchronization instruction signal transmission module comprises synchronization instruction signal transmission chips, the synchronization instruction signal transmission chip comprises a first control pin and a second control pin, the first control pin is connected with the drain of the second MOSFET, the first control pin is configured to receive the second control signal, the second control pin is connected with the drain of the first MOSFET, the second control pin is configured to receive the first control signal; and
the synchronization instruction signal transmission chip further comprises a first input pin, a second input pin and a first output pin, the first input pin is connected with the input interface module, the first input pin is configured to receive the synchronization instruction signal input by the input interface module, the second input pin is connected with the main control chip module, the second input pin is configured to input the synchronization instruction signal generated by the main control chip module, the first output pin is connected with the output interface module, the first output pin is configured to output the synchronization instruction signal.

10. A synchronization circuit, arranged within each camera of a distributed camera system, comprising:
an input interface module, configured to input a synchronization instruction signal;
a detection control module, configured to output a first control signal to a synchronization instruction signal transmission module in a case where the input interface module is connected with a synchronization line; output a detection signal to a main control chip module, and output a second control signal to the synchronization instruction signal transmission module in a case where the input interface module is not connected with the synchronization line;
the main control chip module, configured to output the synchronization instruction signal to the synchronization instruction signal transmission module in a case where the detection signal is received;
the synchronization instruction signal transmission module, configured to transmit the synchronization instruction signal input by the input interface module to the output interface module in a case where the first control signal is received; the synchronization instruction signal transmission module is configured to transmit the synchronization instruction signal generated by the main control chip module to the output interface module in a case where the second control signal is received;
the output interface module, configured to output the synchronization instruction signal to a succeeding camera;
an instruction module, configured to generate a control instruction signal and execute the control instruction signal; wherein the control instruction signal corresponds to the synchronization instruction signal;
an information transmission module, connected between the input interface module and the output interface module of two adjacent cameras, the information transmission module being configured to transmit the control instruction signal;
in a case where the input interface module is connected with the synchronization line, the instruction module receives a control instruction signal from a preceding camera through the information transmission module, executes the control instruction signal based on a corresponding synchronization instruction signal, and sends the control instruction signal to a succeeding camera through the information transmission module; and
in a case where the input interface module is not connected with the synchronization line, the instruction module generates the control instruction signal, executes the control instruction signal based on the corresponding synchronization instruction signal, and sends the control instruction signal to the succeeding camera through the information transmission module.

11. The synchronization circuit according to claim 10, wherein, in a case where the input interface module is connected with the synchronization line, the detection control module outputs the detection signal at a high level, the main control chip module recognizes the operating mode of the camera as a slave mode; in a case where the input interface module is not connected with the synchronization line, the detection control module outputs the detection signal at a low level, and the main control chip module recognizes the operating mode of the camera as a master mode.

12. The synchronization circuit according to claim 10, wherein, the detection control module comprises a first MOSFET and a second MOSFET, a gate of the first MOSFET is connected with the input interface module and a power supply, a drain of the first MOSFET is connected with a gate of the second MOSFET, a source of the first MOSFET is grounded, a source of the second MOSFET is connected with a gate, the source of the second MOSFET is further connected with a power supply, the drain of the first MOSFET is further configured to output the detection signal, and the first control signal, a drain of the second MOSFET is configured to output the second control signal.

13. The synchronization circuit according to claim 12, wherein, the synchronization instruction signal transmission module comprises synchronization instruction signal transmission chips, the synchronization instruction signal transmission chip comprises a first control pin and a second control pin, the first control pin is connected with the drain of the second MOSFET, the first control pin is configured to receive the second control signal, the second control pin is connected with the drain of the first MOSFET, the second control pin is configured to receive the first control signal; and
the synchronization instruction signal transmission chip further comprises a first input pin, a second input pin and a first output pin, the first input pin is connected with the input interface module, the first input pin is configured to receive the synchronization instruction signal input by the input interface module, the second input pin is connected with the main control chip module, the second input pin is configured to input the synchronization instruction signal generated by the main control chip module, the first output pin is connected with the output interface module, the first output pin is configured to output the synchronization instruction signal.

14. The synchronization circuit according to claim 10, wherein, the synchronization circuit further comprises a master clock signal transmission module and a frame synchronization signal transmission module, the input interface module is further configured to input a master clock signal or a frame synchronization signal;
the detection control module is further configured to output the first control signal to the master clock signal transmission module and the frame synchronization signal transmission module in a case where the input interface module is connected with the synchronization line; output the detection signal to the main control chip module, and output the second control signal to the master clock signal transmission module and the frame synchronization signal transmission module in a case where the input interface module is not connected with the synchronization line;
the main control chip module is configured to output the master clock signal to the master clock signal transmission module and output the frame synchronization signal to the frame synchronization signal transmission module in a case where the detection signal is received;
the master clock signal transmission module is configured to transmit the master clock signal input by the input interface module to the output interface module in a case where the first control signal is received; transmit the master clock signal generated by the main control chip module to the output interface module in a case where the second control signal is received;
the frame synchronization signal transmission module is configured to transmit the frame synchronization signal input by the input interface module to the output interface module in a case where the first control signal is received; transmit the frame synchronization signal generated by the main control chip module to the output interface module in a case where the second control signal is received;
a camera module is configured to perform picture capture based on the frame synchronization signal and the master clock signal; and
the output interface module is configured to output the master clock signal or the frame synchronization signal.

15. The synchronization circuit according to claim 14, wherein, the master clock signal transmission module comprises master clock signal transmission chips, the master clock signal transmission chip comprises a third control pin and a fourth control pin, the third control pin is connected with the drain of the second MOSFET, the third control pin is configured to receive the second control signal, the fourth control pin is connected with the drain of the first MOSFET, and the fourth control pin is configured to receive the first control signal; and
the master clock signal transmission chip further comprises a third input pin, a fourth input pin and a second output pin, the third input pin is connected with the input interface module, the third input pin is configured to receive the master clock signal input by the input interface module, the fourth input pin is connected with the main control chip module, the fourth input pin is configured to input the master clock signal generated by the main control chip module, the second output pin is connected with the output interface module, and the second output pin is configured to output the master clock signal.

16. The synchronization circuit according to claim 15, wherein, the frame synchronization signal transmission module comprises frame synchronization signal transmission chips, the frame synchronization signal transmission chip comprises a fifth control pin and a sixth control pin, the fifth control pin is connected with the drain of the second MOSFET, the fifth control pin is configured to receive the second control signal, the sixth control pin is connected with the drain of the first MOSFET, the sixth control pin is configured to receive the first control signal; and
the frame synchronization signal transmission chip further comprises a fifth input pin, a sixth input pin and a third output pin, the fifth input pin is connected with the input interface module, the fifth input pin is configured to receive the frame synchronization signal input by the input interface module, the sixth input pin is connected with the main control chip module, the sixth input pin is configured to input the frame synchronization signal generated by the main control chip module, the third output pin is connected with the output interface module, and the third output pin is configured to output the frame synchronization signal.

17. The synchronization circuit according to claim 16, wherein, the master clock signal transmission chip is a fast logic chip, a model of the master clock signal transmission chip is SN74IVC2G126; the frame synchronization signal transmission chip is a fast logic chip, and a model of the frame synchronization signal transmission chip is SN74IVC2G126.

18. The synchronization circuit according to claim 13, wherein, the synchronization instruction transmission chip is a fast logic chip, and a model of the synchronization instruction transfer chip is SN74IVC2G126.

19. A distributed camera system, comprising:
a plurality of cameras, each internally provided with a synchronization circuit in one-to-one correspondence, wherein one of the cameras serves as a master camera, the rest of the cameras are slave cameras, the operating mode of the master camera is a master mode, and the operating mode of the slave cameras is a slave mode;
a synchronization line, with one end connected with an output interface module of the master camera and the other end connected with an input interface module of the slave camera, or connected between the input interface module and the output interface module of two adjacent slave cameras for transmitting a control instruction signal, a synchronization instruction signal, a master clock signal, and/or a frame synchronization signal;
wherein each camera generates a picture for subsequent picture synchronized presentation based on the master clock signal and the frame synchronization signal; each camera performs synchronization control of all cameras based on the control instruction signal and the synchronization instruction signal.

20. The distributed camera system according to claim 19, comprising:
an input interface module, configured to input a master clock signal or a frame synchronization signal;
a detection control module, configured to output a first control signal to a master clock signal transmission module, a frame synchronization signal transmission module, and a synchronization instruction signal transmission module in a case where the input interface module is connected with the synchronization line; output a detection signal to a main control chip module, and output a second control signal to the master clock signal transmission module, the frame synchronization signal transmission module, and the synchronization instruction signal transmission module in a case where the input interface module is not connected with the synchronization line;
the main control chip module, configured to output the master clock signal to the master clock signal transmission module, output the frame synchronization signal to the frame synchronization signal transmission module, and output the synchronization instruction signal to the synchronization instruction signal transmission module in a case where the detection signal is received;
the master clock signal transmission module, configured to transmit the master clock signal input by the input interface module to the output interface module in a case where the first control signal is received; transmit the master clock signal generated by the main control chip module to the output interface module in a case where the second control signal is received;
the frame synchronization signal transmission module, configured to transmit the frame synchronization signal input by the input interface module to the output interface module in a case where the first control signal is received; transmit the frame synchronization signal generated by the main control chip module to the output interface module in a case where the second control signal is received;
the synchronization instruction signal transmission module, configured to transmit the synchronization instruction signal input by the input interface module to the output interface module in a case where the first control signal is received; the synchronization instruction signal transmission module being configured to transmit the synchronization instruction signal generated by the main control chip module to the output interface module in a case where the second control signal is received;
a camera module, configured to perform picture capture based on the frame synchronization signal and the master clock signal;
the output interface module, configured to output the master clock signal or the frame synchronization signal, the output interface module being configured to output the synchronization instruction signal to the succeeding camera;
an instruction module, configured to generate a control instruction signal and execute the control instruction signal; wherein the control instruction signal corresponds to the synchronization instruction signal;
an information transmission module, connected between the input interface module and the output interface module of two adjacent cameras, the information transmission module being configured to transmit the control instruction signal;
in a case where the input interface module is connected with the synchronization line, the instruction module receives the control instruction signal from the preceding camera through the information transmission module, executes the control instruction signal based on the corresponding synchronization instruction signal, and sends the control instruction signal to the succeeding camera through the information transmission module; and
in a case where the input interface module is not connected with the synchronization line, the instruction module generates the control instruction signal, executes the control instruction signal based on the corresponding synchronization instruction signal, and sends the control instruction signal to the succeeding camera through the information transmission module.
